(19) United States
(12) Patent Application Publication
(10) Pub. No.: US 2023/0189562 A1
(43) Pub. Date: Jun. 15, 2023

(54) DISPLAY APPARATUS HAVING A LIGHT-EMITTING DEVICE

(71) Applicant: LG Display Co., Ltd., Seoul (KR)

(72) Inventors: Geum Young LEE, Paju-si (KR); Jeong Oh KIM, Paju-si (KR); Myung Jae YOO, Paju-si (KR); Seong Ho KANG, Paju-si (KR)

(73) Assignee: LG Display Co., Ltd., Seoul (KR)

(21) Appl. No.: 17/940,794

(22) Filed: Sep. 8, 2022

(30) Foreign Application Priority Data
Dec. 14, 2021 (KR) 10-2021-0178498

(51) Int. Cl. H01L 51/52

(52) U.S. Cl. CPC H01L 51/529; H01L 51/5243; H01L 27/3246

(57) ABSTRACT

A display apparatus can include at least one light-emitting device on a device substrate, an encapsulating element on the device substrate and covering the light-emitting device, an encapsulation substrate on the encapsulating element and including a metal, and a surface particle layer surrounding at least a portion of the encapsulation substrate. The surface particle layer can include metal particles dispersed at a surface of the encapsulation substrate. The surface particle layer can have a thermal conductivity that is higher than a thermal conductivity of the encapsulation substrate.

### CROSS-REFERENCE TO RELATED APPLICATIONS

This application claims the benefit of priority to Korean Patent Application No. 10-2021-0178498 filed in the Republic of Korea on Dec. 14, 2021, the entirety of which is hereby incorporated by reference as if fully set forth herein.

### BACKGROUND OF THE DISCLOSURE

### Field of the Invention

The present disclosure relates to a display apparatus capable of realizing an image provided to a user using light emitted from a light-emitting device.

### Discussion of the Related Art

Generally, a display apparatus provides an image to user. For example, the display apparatus may include at least one light-emitting device on a device substrate. The light-emitting device may emit light displaying a specific color. For example, the light-emitting device may include a first electrode, a light-emitting layer and a second electrode, which are sequentially stacked on the device substrate.

The light-emitting layer may be vulnerable to moisture and heat. The display apparatus may further include an encapsulating element covering the light-emitting device to prevent deterioration of the light-emitting layer due to penetration of external moisture. An encapsulation substrate may be disposed on the encapsulating element. The encapsulation substrate may have a hardness that is greater than or equal to a certain level. External impacts applied to the light-emitting device may be blocked and/or relieved by the encapsulation substrate. For example, the encapsulation substrate may include a metal.

In the display apparatus, heat generated by the operation of the light-emitting device may be emitted through the encapsulation substrate. However, metals with high-strength generally have low thermal-conductivity. Thus, in the display apparatus, the quality of the image provided to the user may become deteriorated due to low heat dissipation efficiency. Also, the light-emitting device is vulnerable to damage from external impacts that may occur over time, such as dropping or bumping the device, which can further degrade image quality.

### SUMMARY OF THE DISCLOSURE

Accordingly, the present disclosure is directed to a display apparatus that substantially obviates one or more problems due to limitations and disadvantages of the related art.

An object of the present disclosure is to provide a display apparatus capable of sufficiently securing rigidity of the encapsulation substrate to block and/or relieve external impacts and improving image quality.

Another object of the present disclosure is to provide a display apparatus capable of preventing damage to the light-emitting device due to external impacts and improving the heat dissipation efficiency.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising a device substrate. At least one light-emitting device and an encapsulating element are disposed on the device substrate. The encapsulating element covers the light-emitting device. An encapsulation substrate is disposed on the encapsulating element. The encapsulation substrate includes a metal. The encapsulation substrate is surrounded by a surface particle layer. The surface particle layer is made of metal particles dispersed at a surface of the encapsulation substrate. The surface particle layer has a thermal conductivity that is higher than the encapsulation substrate. A surface roughness of the surface particle layer is greater than a surface roughness of the encapsulation substrate.

The encapsulating element may be in contact with the surface particle layer. The surface particle layer may include a region which is disposed outside of the encapsulating element.

The encapsulation substrate may include a lower surface facing toward the device substrate, an upper surface opposite to the device substrate, and a side surface disposed between the lower surface and the upper surface. The surface particle layer may include a lower particle layer disposed at the lower surface of the encapsulation substrate, an upper particle layer disposed at the upper surface of the encapsulation substrate, and a side particle layer disposed at the side surface of the encapsulation substrate. A surface roughness of the lower particle layer may be greater than a surface roughness of the upper particle layer.

A surface roughness of the side particle layer may be different than the surface roughness of the upper particle layer.

A thermal conductivity of the upper particle layer may be higher than a thermal conductivity of the lower particle layer.

A thermal conductivity of the side particle layer may be different than the thermal conductivity of the upper particle layer.

A pad portion may be disposed on the device substrate. The pad portion may be spaced away from the encapsulating element. The side surface of the encapsulation substrate may include a front portion facing toward the pad portion. The surface particle layer may include a first region disposed on the front portion of the encapsulation substrate and a second region disposed outside of the front portion. A thermal conductivity of the first region may be higher than a thermal conductivity of the second region.

A surface roughness of the first region may be different than a surface roughness of the second region.

In another embodiment, there is provided a display apparatus including a device substrate. At least one light-emitting device is disposed on the device substrate. An encapsulation substrate is disposed on the light-emitting device. The encapsulation substrate includes a metal. A lower particle layer is disposed at a lower surface of the encapsulation substrate facing toward the device substrate. The lower particle layer is made of first particles and second particles, which are dispersed at the lower surface of the encapsulation substrate. An encapsulating element is disposed between the light-emitting device and the lower particle layer. An upper particle layer is disposed at an upper surface of the encapsulation substrate opposite to the device substrate. The upper particle layer is made of the first particles and third particles, which are dispersed at the upper surface of the encapsulation substrate. The first particles include the same metal as the encapsulation substrate. The second particles and the third particles include a metal having a thermal conductivity higher than the first particles.

A thermal conductivity of the third particles may be higher than a thermal conductivity of the second particles.

Each of the lower particle layer and the upper particle layer may include a first particle layer in contact with the encapsulation substrate and a second particle layer on the first particle layer. The content of the first particles in the second particle layer may be less than the content of the first particles in the first particle layer.

A third particle layer may be disposed between the first particle layer and the second particle layer. The content of the first particles in the third particle layer may be between the content of the first particles in the first particle layer and the content of the first particles in the second particle layer.

The encapsulation substrate may include a side surface between the lower surface and the upper surface. A side particle layer may be disposed at the side surface of the encapsulation substrate. The side particle layer may be made of the first particles and fourth particles, which are dispersed at the side surface of the encapsulation substrate. A thermal conductivity of the fourth particles may be higher than the thermal conductivity of the first particles and the thermal conductivity of the second particles.

The fourth particles may include the same material as the third particles.

The side particle layer may be in contact with the lower particles layer and the upper particle layer.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain principles of the present disclosure. In the drawings:

FIG. 1 is a view schematically showing a display apparatus according to an embodiment of the present disclosure;

FIG. 2 is an enlarged view of K region in FIG. 1 according to an embodiment of the present disclosure;

FIG. 3 is an enlarged view of P region in FIG. 2 according to an embodiment of the present disclosure; and

FIGS. 4 to 10 are views showing the display apparatus according to embodiments of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification, and in the drawings, the lengths and thickness of layers and regions may be exaggerated for convenience. It will be understood that, when a first element is referred to as being “on” a second element, although the first element may be disposed on the second element to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

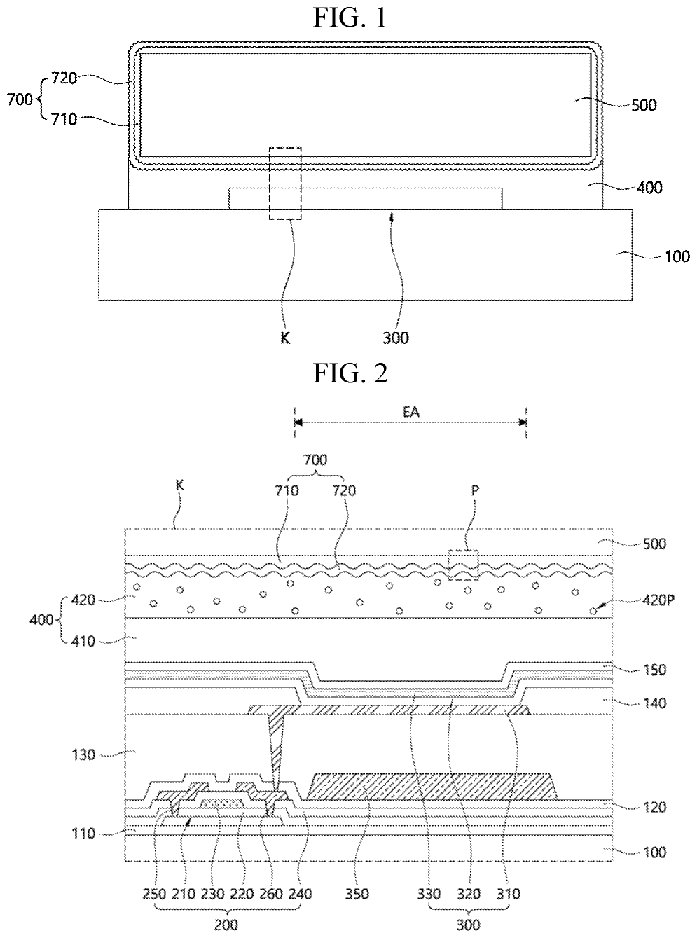

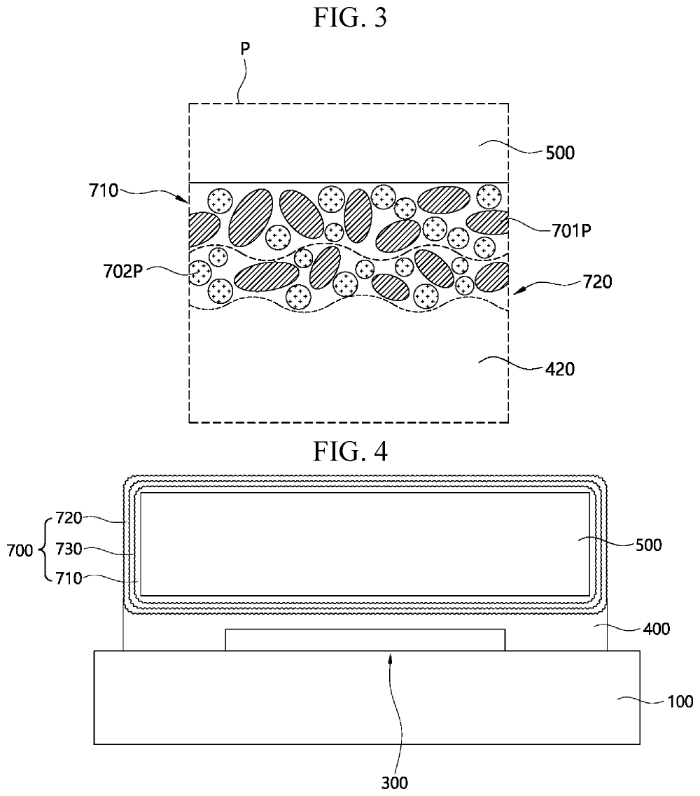

FIG. 1 is a view schematically showing a display apparatus according to an embodiment of the present disclosure. FIG. 2 is an enlarged view of K region in FIG. 1. FIG. 3 is an enlarged view of P region in FIG. 2.

Referring to FIGS. 1 to 3, the display apparatus according to an embodiment of the present disclosure can include a device substrate 100. The device substrate 100 can include an insulating material. The device substrate 100 can include a transparent material. For example, the device substrate 100 can include glass or plastic.

At least one pixel driving circuit can be disposed on the device substrate 100. The pixel driving circuit can generate a driving current corresponding to a data signal according to a gate signal. For example, the pixel driving circuit can include at least one thin film transistor 200. The thin film transistor 200 can include a semiconductor pattern 210, a gate insulating layer 220, a gate electrode 230, an interlayer insulating layer 240, a source electrode 250, and a drain electrode 260.

The semiconductor pattern 210 can be disposed close to the device substrate 100. The semiconductor pattern 210 can include a semiconductor material. For example, the semiconductor pattern 210 can include an amorphous Si, a poly Si and an oxide semiconductor. The oxide semiconductor can include a metal oxide. For example, the semiconductor pattern 210 can include IGZO.

The semiconductor pattern 210 can include a source region, a drain region and a channel region. The channel region can be disposed between the source region and the drain region. The source region and the drain region can have a resistance lower than the channel region. For example, the source region and the drain region can include a conductorized region of an oxide semiconductor. The channel region can be a region of an oxide semiconductor, which is not conductorized.

The gate insulating layer 220 can include an insulating material. For example, the gate insulating layer 220 can include an inorganic insulating material, such as silicon oxide (SiO) and silicon nitride (SiN). The gate insulating layer 220 can be disposed on the semiconductor pattern 210. The gate insulating layer 220 can extend beyond the semiconductor pattern 210. For example, a side surface of the semiconductor pattern 210 can be covered by the gate insulating layer 220.

The gate electrode 230 can include a conductive material. For example, the gate electrode 230 can include a metal, such as aluminum (Al), titanium (Ti), copper (Cu), chrome (Cr), molybdenum (Mo) and tungsten (W). The gate electrode 230 can be disposed on the gate insulating layer 220. For example, the gate electrode 230 can be insulated from the semiconductor pattern 210 by the gate insulating layer 220. The gate electrode 230 can overlap with the channel region of the semiconductor pattern 210. For example, the channel region of the semiconductor pattern 210 can have an electrical conductivity corresponding to a voltage applied to the gate electrode 230.

The interlayer insulating layer 240 can include an insulating material. For example, the interlayer insulating layer 240 can include an inorganic insulating material, such as silicon oxide (SiO) and silicon nitride (SiN). The interlayer insulating layer 240 can be disposed on the gate electrode 230. The interlayer insulating layer 240 can extend beyond the gate electrode 230. For example, a side surface of the gate electrode 230 can be covered by the interlayer insulating layer 240. The interlayer insulating layer 240 can be in direct contact with the gate insulating layer 220 at areas outside of the gate electrode 230 (e.g., the gate electrode 230 can be disposed between a portion of the interlayer insulating layer 240 and gate insulating layer 220).

The source electrode 250 can include a conductive material. For example, the source electrode 250 can include a metal, such as aluminum (Al), titanium (Ti), copper (Cu), chrome (Cr), molybdenum (Mo) and tungsten (W). The source electrode 250 can be disposed on the interlayer insulating layer 240. For example, the source electrode 250 can be insulated from the gate electrode 230 by the interlayer insulating layer 240. The source electrode 250 can include a material different from the gate electrode 230.

The source electrode 250 can be electrically connected to the source region of the semiconductor pattern 210. For example, the gate insulating layer 220 and the interlayer insulating layer 240 can include a source contact hole partially exposing the source region of the semiconductor pattern 210. The source electrode 250 can be in direct contact with the source region of the semiconductor pattern 210 through the source contact hole.

The drain electrode 260 can include a conductive material. For example, the drain electrode 260 can include a metal, such as aluminum (Al), titanium (Ti), copper (Cu), chrome (Cr), molybdenum (Mo) and tungsten (W). The drain electrode 260 can be disposed on the interlayer insulating layer 240. For example, the drain electrode 260 can be disposed on the same layer as the source electrode 250. The drain electrode 260 can include the same material as the source electrode 250. The drain electrode 260 can be insulated from the gate electrode 230 by the interlayer insulating layer 240. For example, the drain electrode 260 can include a material different from the gate electrode 230.

The drain electrode 260 can be electrically connected to the drain region of the semiconductor pattern 210. The drain electrode 260 can be spaced away from the source electrode 250. For example, the gate insulating layer 220 and the interlayer insulating layer 240 can include a drain contact hole partially exposing the drain region of the semiconductor pattern 210. The drain electrode 260 can be in direct contact with the drain region of the semiconductor pattern 210 through the drain contact hole.

A device buffer layer 110 can be disposed between the device substrate 100 and the pixel driving circuit. The device buffer layer 110 can prevent pollution or off-gassing due to the device substrate 100 in a process of forming the thin film transistor 200. For example, an upper surface of the device substrate 100 toward the thin film transistor 200 can be completely covered by the device buffer layer 110. The device buffer layer 110 can include an insulating material. For example, the device buffer layer 110 can include an inorganic insulating material, such as silicon oxide (SiO) and silicon nitride (SiN).

A lower passivation layer 120 can be disposed on the pixel driving circuit. The lower passivation layer 120 can prevent damage to the pixel driving circuit due to external impacts and moisture. For example, a surface of the pixel driving circuit opposite to the device substrate 100 can be completely covered by the lower passivation layer 120. The lower passivation layer 120 can extend beyond the pixel driving circuit. For example, the lower passivation layer 120 can extend along the surface of the thin film transistor 200 (e.g., lower passivation layer 120 can cover across the top of the thin film transistor 200).

An over-coat layer 130 can be disposed on the lower passivation layer 120. The over-coat layer 130 can remove any thickness differences due to the pixel driving circuit (e.g., providing a planarization function). For example, an upper surface of the over-coat layer 130 opposite to the device substrate 100 can be a flat surface. The over-coat layer 130 can extend beyond the pixel driving circuit. For example, the upper surface of the over-coat layer 130 can extend parallel with the upper surface of the device substrate 100. The over-coat layer 130 can include an insulating material. The over-coat layer 130 can include a material different from the lower passivation layer 120. For example, the over-coat layer 130 can include an organic insulating material.

At least one light-emitting device 300 can be disposed on the over-coat layer 130. The light-emitting device 300 can emit light displaying a specific color. For example, the light-emitting device 300 can include a first electrode 310, a light-emitting layer 320 and a second electrode 330, which are sequentially stacked on the device substrate 100.

The first electrode 310 can include a conductive material. The first electrode 310 can include a transparent material. For example, the first electrode 510 can be a transparent electrode made of transparent conductive material, such as ITO and IZO.

The first electrode 310 can be electrically connected to the pixel driving circuit. For example, the lower passivation layer 120 and the over-coat layer 130 can include an electrode contact hole partially exposing the drain electrode 260 of the thin film transistor 200. The first electrode 310 can be in direct contact with the drain electrode 260 of the thin film transistor 200 through the electrode contact hole.

The first electrode 310 can extend beyond the pixel driving circuit. For example, the first electrode 310 can include a region overlapping with the pixel driving circuit and a region which does not overlap the pixel driving circuit. The drain electrode 260 of the thin film transistor 200 can be connected to the region of the first electrode 310 overlapping with the pixel driving circuit.

The light-emitting layer 320 can generate light having luminance corresponding to a voltage difference between the first electrode 310 and the second electrode 330. For example, the light-emitting layer 320 can include an emission material layer (EML) having an emission material. The emission material can include an organic material, an inorganic material or a hybrid material. For example, the display apparatus according to the embodiment of the present disclosure can be an organic light-emitting display apparatus including an organic emission material.

The light-emitting layer 320 can have a multi-layer structure. For example, the light-emitting layer 320 can further include at least one of a hole injection layer (HIL), a hole transport layer (HTL), an electron transport layer (ETL) and an electron injection layer (EIL). Thus, in the display apparatus according to the embodiment of the present disclosure, the emission efficiency of the light-emitting layer 320 can be improved.

The second electrode 330 can include a conductive material. The second electrode 330 can include a material different from the first electrode 310. The transmittance of the second electrode 330 can be lower than the transmittance of the first electrode 310. The second electrode 330 can have a reflectance higher than the first electrode 310. For example, the second electrode 330 can include a metal, such as aluminum (Al) and silver (Ag). Thus, in the display apparatus according to the embodiment of the present disclosure, the light generated by the light-emitting layer 320 can be emitted to the outside through the first electrode 310 and the device substrate 100.

A bank insulating layer 140 can be disposed on the over-coat layer 130. The bank insulating layer 140 can define an emission area EA. For example, the bank insulating layer 140 can cover an edge of the first electrode 310. The light-emitting layer 320 and the second electrode 330 can be stacked on a portion of the first electrode 310 exposed by the bank insulating layer 140. The bank insulating layer 140 can include an insulating material. For example, the bank insulating layer 140 can include an organic insulating material. The bank insulating layer 140 can include a material different from the over-coat layer 130.

The emission area EA can be disposed outside the pixel driving circuit. For example, the thin film transistor 200 can overlap the bank insulating layer 140. Thus, in the display apparatus according to the embodiment of the present disclosure, the light emitted from the emission area EA may be not blocked by the pixel driving circuit.

A color filter 350 can be disposed between the device substrate 100 and the light-emitting device 300. The color filter 350 can realize various colors using light generated by the light-emitting layer 320. The light emitted from the light-emitting device 300 can be emitted to the outside through the color filter 350. For example, the color filter 350 can be disposed on a path of the light emitted from the light-emitting device 300. The color filter 350 can be disposed between the lower passivation layer 120 and the over-coat layer 130. A thickness difference due to the color filter 350 can be removed by the over-coat layer 130. The color filter 350 can overlap with the emission area EA. For example, the thin film transistor 200 can be disposed outside the color filter 350 (e.g., in an area adjacent to the color filter 350, see FIG. 3).

An encapsulating element 400 can be disposed on the light-emitting device 300. The encapsulating element 400 can prevent damage to the light-emitting device 300 due to external moisture and impacts. For example, the encapsulating element 400 can include moisture-absorbing particles 420p. The encapsulating element 400 can extend beyond the light-emitting device 300. For example, the device buffer layer 110, the thin film transistor 200, the lower passivation layer 120, the over-coat layer 130, the light-emitting device 300 and the bank insulating layer 140 can be completely covered by the encapsulating element 400. The encapsulating element 400 can include a region in direct contact with the device substrate 100 (e.g., along the edges or perimeter of the light-emitting device 300).

The encapsulating element 400 can include an insulating material. For example, the encapsulating element 400 can include olefin-based material. The encapsulating element 400 can have a multi-layer structure. For example, the encapsulating element 400 can have a stacked structure of a first encapsulating layer 410 and a second encapsulating layer 420. The first encapsulating layer 410 can be disposed between the light-emitting device 300 and the second encapsulating layer 420. For example, a lower surface of the second encapsulating layer 420 facing toward the device substrate 100 can be in direct contact with the first encapsulating layer 410. The moisture-absorbing particles 420p can be dispersed in the second encapsulating layer 420. Thus, in the display apparatus according to the embodiment of the present disclosure, the stress applied to the light-emitting device 300 due to expansion of the moisture-absorbing particles 420p can be relieved by the first encapsulating layer 410 (e.g., a pliant or cushiony type of material that accommodates or allows for expansion of the moisture-absorbing particles 420p). For example, the first encapsulating layer 410 can include a material different from the second encapsulating layer 420.

An upper passivation layer 150 can be disposed between the light-emitting device 300 and the encapsulating element 400. The upper passivation layer 150 can include an insulating material. The upper passivation layer 150 can include a material different from the encapsulating element 400. For example, the upper passivation layer 150 can include an inorganic insulating material, such as silicon oxide (SiO) and silicon nitride (SiN). Thus, in the display apparatus according to the embodiment of the present disclosure, penetration of external moisture can be blocked by the upper passivation layer 150 and the encapsulating element 400. Therefore, in the display apparatus according to the embodiment of the present disclosure, deterioration of the light-emitting layer 320 due to external moisture can be effectively prevented by the upper passivation layer 150 and the encapsulating element 400.

An encapsulation substrate 500 can be disposed on the encapsulating element 400. The encapsulation substrate 500 can prevent damage to the pixel driving circuit and the light-emitting device 300 due to external impacts. For example, external impacts applied in a direction toward the light-emitting device 300 can be blocked and/or relieved by the encapsulation substrate 500. The encapsulation substrate 500 can have hardness greater than or equal to a certain level. For example, the encapsulation substrate 500 can include a metal, such as nickel (Ni) and iron (Fe). The encapsulation substrate 500 can be a plate shape. For example, a surface of the encapsulation substrate 500 can be a flat.

A surface particle layer 700 can be disposed at the surface of the encapsulation substrate 500. For example, the surface particle layer 700 can be made of metal particles 701p and 702p, which are dispersed at the surface of the encapsulation substrate 500. The metal particles 701p and 702p can be directly deposited at the surface of the encapsulation substrate 500. For example, the surface particle layer 700 can be formed by a sputtering process. Also, the metal particles 701p and 702p can have spherical or ovoid shapes, but are not limited to these. The metal particles 701p can have an ovoid shape and be larger than the metal particles 702p, which can have a spherical shape. Thus, in the display apparatus according to the embodiment of the present disclosure, a surface roughness of the surface particle layer 700 can be greater than a surface roughness of the encapsulation substrate 500. The surface particle layer 700 can extend along the surface of the encapsulation substrate 500. For example, the encapsulation substrate 500 can be surrounded by the surface particle layer 700.

A portion of the surface particle layer 700 which is disposed at a lower surface of the encapsulation substrate 500 facing toward the device substrate 100 can be in direct contact with the encapsulating element 400. Thus, in the display apparatus according to the embodiment of the present disclosure, a contact area between the encapsulating element 400 and the surface particle layer 700 can be increased by a rough surface of the surface particle layer 700. That is, in the display apparatus according to the embodiment of the present disclosure, the bonding force between the encapsulating element 400 and the surface particle layer 700 can be increased (e.g., since the rough surface of the surface particle layer 700 provides a larger amount of surface area). Therefore, in the display apparatus according to the embodiment of the present disclosure, the separation of the surface particle layer 700 from the encapsulating element 400 can be prevented. And, in the display apparatus according to the embodiment of the present disclosure, a gap can be prevented from forming and peeling can be prevented from occurring between the encapsulating element 400 and the surface particle layer 700.

Furthermore, in the display apparatus according to the embodiment of the present disclosure, the rough surface of the surface particle layer 700 can be in close contact with the encapsulating element 400, such that the heat transfer efficiency between the encapsulating element 400 and the surface particle layer 700 can be increased. That is, in the display apparatus according to the embodiment of the present disclosure, heat generated by the operation of the pixel driving circuit and/or the light-emitting device 300 can be rapidly transferred to the surface particle layer 700 through the encapsulating element 400. Therefore, in the display apparatus according to the embodiment of the present disclosure, the heat dissipation efficiency can be improved (e.g., the surface particle layer 700 and the encapsulation substrate 500 can act as a large heat sink).

The metal particles 701p and 702p can comprises first particles 701p including the same material as the encapsulation substrate 500, and second particles 702p having a thermal conductivity higher than the first particles 701p. Table 1 shows the heat transfer coefficients of nickel (Ni), iron (Fe), aluminum (Al) and copper (Cu), average surface roughness of the layers made of nickel (Ni), iron (Fe), aluminum (Al) and copper (Cu), and atomic radii of nickel (Ni), iron (Fe), aluminum (Al) and copper (Cu).

TABLE 1

| | heat transfer | average surface | atomic |
|---|---|---|---|
| material | coefficients (W/mk) | roughness | radii |
| nickel (Ni) | 91 | 20 | 135 |
| iron (Fe) | 80 | 2 | 140 |
| aluminum (Al) | 237 | 8 | 143 |
| copper (Cu) | 385 | 12.6 | 135 |

Referring to Table 1, aluminum (Al) and copper (Cu) have heat transfer coefficients that are higher than nickel (Ni) and iron (Fe), and a surface of the layer made of only aluminum (Al) or copper (Cu) is not flat. For example, in the display apparatus according to the embodiment of the present disclosure, the encapsulation substrate 500 can include nickel (Ni) and iron (Fe), the first particles 701p can include at least one of nickel (Ni) and iron (Fe), and the second particles 702p can include aluminum (Al) or copper (Cu). Thus, in the display apparatus according to the embodiment of the present disclosure, the bonding force between the encapsulation substrate 500 and the surface particle layer 700 can be increased by the first particles 701p. Therefore, in the display apparatus according to the embodiment of the present disclosure, the separation or peeling of the surface particle layer 700 from the encapsulation substrate 500 can be prevented. And, in the display apparatus according to the embodiment of the present disclosure, a gap can be prevented from forming between the encapsulation substrate 500 and the surface particle layer 700. The surface particle layer 700 can have a thermal conductivity higher than the encapsulation substrate 500 by the second particles 702p. Thus, in the display apparatus according to the embodiment of the present disclosure, the heat generated by the operation of the pixel driving circuit and/or the light-emitting device 300 can move through the surface particle layer 700, rapidly. That is, in the display apparatus according to the embodiment of the present disclosure, the influence of materials constituting the encapsulation substrate 500 on the heat dissipation efficiency can be reduced. That is, in the display apparatus according to the embodiment of the present disclosure, the degree of freedom for a material of the encapsulation substrate 500 can be improved. Therefore, in the display apparatus according to the embodiment of the present disclosure, the external impact applied to the pixel driving circuit and the light-emitting device 300 can be sufficiently blocked or relieved, and the heat dissipation efficiency can be improved.

The surface particle layer 700 can have a stacked structure of a first particle layer 710 and a second particle layer 720. The first particle layer 710 can be disposed between the encapsulation substrate 500 and the second particle layer 720. For example, the first particle layer 710 and the second particle layer 720 can extend side by side along the surface of the encapsulation substrate 500. The first particle layer 710 can be in direct contact with the encapsulation substrate 500 and the second particle layer 720. The first particles 701p and the second particles 702p can be dispersed in the first particle layer 710 and the second particle layer 720. The content of the first particles 701p can decrease as the distance from the encapsulation substrate 500 increases. For example, the content of the first particles 701p in the second particle layer 720 can be less than the content of the first particles 701p in the first particle layer 710. The content of the second particles 702p in the second particle layer 720 can be greater than the content of the second particles 702p in the first particle layer 710. For example, a surface roughness of the first particle layer 710 can be different from a surface roughness of the second particle layer 720. Thus, in the display apparatus according to the embodiment of the present disclosure, the separation of the surface particle layer 700 from the encapsulation substrate 500 can be prevented by the first particle layer 710, and the heat generated by the operation of the pixel driving circuit and/or the light-emitting device 300 can be rapidly dissipated to the outside through the second particle layer 720 of the surface particle layer 700. In other words, in order to minimize the stress difference with the encapsulation substrate 500 and to prevent distortion or cracking, the content of the first particles 701p in the first particle layer 710 can be greater than the content of the second particles 702p having a heat transfer coefficient higher than the first particles 701p in the first particle layer 710. Herein, the first particles 701p can include particles constituting the encapsulation substrate 500. And, in order to effectively dissipate the heat absorbed by the surface particle layer 700, the content of the second particles 702p having a heat transfer coefficient higher than the first particles 701p in the second particle layer 710 can be greater than the content of the first particles 701p in the second particle layer 720. Thus, in the display apparatus according to the embodiment of the present disclosure, the heat dissipation efficiency can be improved without a decrease in physical strength.

Accordingly, the display apparatus according to the embodiment of the present disclosure can include the encapsulating element 400 covering the light-emitting device 300, the encapsulation substrate 500 on the encapsulating element 400, and the surface particle layer 700 surrounding the encapsulation substrate 500, in which the surface particle layer 700 can be made of the metal particles 701p and 702p which are dispersed at the surface of the encapsulation substrate 500, such that the surface particle layer 700 can have the surface roughness greater than the encapsulation substrate 500. Thus, in the display apparatus according to the embodiment of the present disclosure, the surface particle layer 700 can be in close contact with the encapsulating element 400 and the encapsulation substrate 500, and the heat generated by the operation of the pixel driving circuit and/or the light-emitting device 300 can be rapidly dissipated through the surface particle layer 700. Therefore, in the display apparatus according to the embodiment of the present disclosure, the damage of the light-emitting device 300 due to the external impact can be sufficiently prevented, and the heat dissipation efficiency can be effectively improved.

And, in the display apparatus according to the embodiment of the present disclosure, a gap can be prevented from forming between the encapsulating element 400 and the surface particle layer 700 and between the surface particle layer 700 and the encapsulation substrate 500 by the rough surface of the surface particle layer 700 and the first particles 701p. Thus, in the display apparatus according to the embodiment of the present disclosure, a decrease in physical strength between the encapsulating element 400, the surface particle layer 700 and the encapsulation substrate 500 can be prevented. And, in the display apparatus according to the embodiment of the present disclosure, the penetration of the external moisture through interface between the encapsulating element 400, the surface particle layer 700 and the encapsulation substrate 500 can be prevented. Therefore, in the display apparatus according to the embodiment of the present disclosure, the quality of the image provided to the user can be improved and a lifetime of the device can be extended.

The display apparatus according to the embodiment of the present disclosure is described that the surface particle layer 700 has a double-layer structure of the first particle layer 710 and the second particle layer 720. However, the display apparatus according to another embodiment of the present disclosure can include the surface particle layer 700 having various structures. For example, in the display apparatus according to another embodiment of the present disclosure, the surface particle layer 700 can have a triple-layer structure in which a third particle layer 730 is disposed between the first particle layer 710 and the second particle layer 720, as shown in FIG. 4. The first particles and the second particles can be dispersed in the third particle layer 730. The content of the first particles including the same material as the encapsulation substrate 500 can sequentially decrease as a distance away from the encapsulation substrate 500 increases. For example, the content of the first particles in the third particle layer 730 can be between the content of the first particles in the first particle layer 710 and the content of the first particles in the second particle layer 720. The content of the second particles can sequentially increase as a distance away from the encapsulation substrate 500 increases. For example, the content of the second particles in the third particle layer 730 can be between the content of the second particles in the first particle layer 710 and the content of the second particles in the second particle layer 720. Thus, in the display apparatus according to another embodiment of the present disclosure, the thermal conductivity of the surface particle layer 700 can gradually increase as a distance away from the encapsulation substrate 500 increases. Therefore, the display apparatus according to another embodiment of the present disclosure can prevent gaps in the surface particle layer 700, and effectively improve the heat dissipation efficiency using the surface particle layer 700. In other words, in order to minimize the stress difference with the encapsulation substrate 500 and to prevent distortion or cracking, the content of the first particles in the first particle layer 710 can be greater than the content of the second particles having a high heat transfer coefficient in the first particle layer 710. Herein, the first particles can include particles constituting the encapsulation substrate 500. In order to effectively dissipate the heat absorbed by the surface particle layer 700, the content of the second particles having a high heat transfer coefficient in the second particle layer 710 can be greater than the content of other particles in the second particle layer 720. And, in order to provide heat transfer and stress matching, the content of the second particles having a high heat transfer coefficient in the third particle layer 730 disposed between the first particle layer 710 and the second particle layer 720 can be greater than the content of the second particle layer in the first particle layer 710 and be less than the content of the second particle layer in the second particle layer 720.

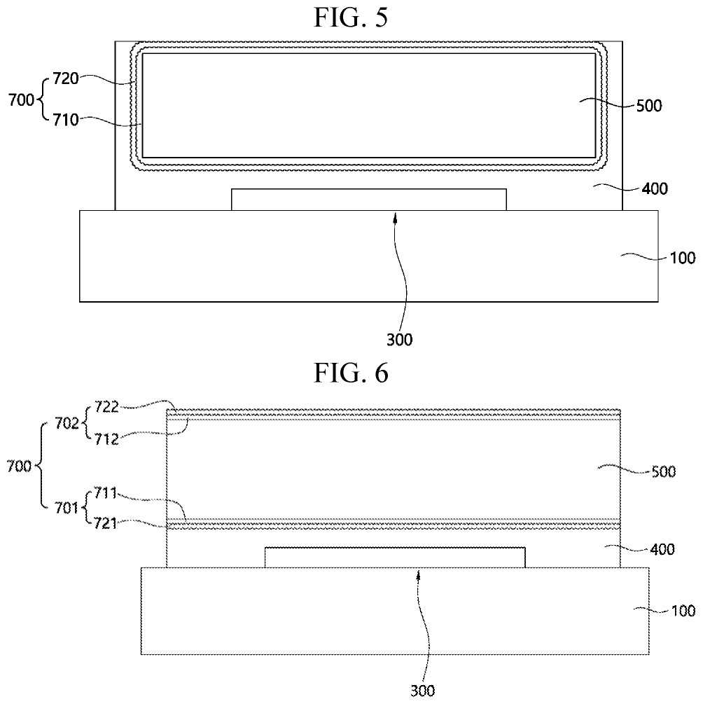

The display apparatus according to the embodiment of the present disclosure is described that a horizontal width of the encapsulating element 400 is the same as a maximum width of the surface particle layer 700. However, in the display apparatus according to another embodiment of the present disclosure, the encapsulating element 400 can have a size larger than the surface particle layer 700. For example, in the display apparatus according to another embodiment of the present disclosure, the encapsulating element 400 can extend on a side surface of the encapsulation substrate 500, as shown in FIG. 5. That is, in the display apparatus according to another embodiment of the present disclosure, a portion of the surface particle layer 700 disposed on the side surface of the encapsulation substrate 500 can be covered by the encapsulating element 400. Thus, in the display apparatus according to another embodiment of the present disclosure, the damage of a signal cable which is disposed on a side surface of the encapsulating element 400 and the side surface of the encapsulation substrate 500, and is electrically connected to external terminal due to the rough surface of the surface particle layer 700 can be prevented. The heat generated by the operation of the pixel driving circuit and/or the light-emitting device 300 can move through the second particle layer 720 of the surface particle layer 700. Therefore, in the display apparatus according to the embodiment of the present disclosure, the pixel driving circuit and the light-emitting device 300 can be stably operated.

The display apparatus according to the embodiment of the present disclosure is described that the surface particle layer 700 completely surrounds the encapsulation substrate 500. However, in the display apparatus according to another embodiment of the present disclosure, the surface particle layer 700 can be disposed only at a portion of the encapsulation substrate 500. For example, in the display apparatus according to another embodiment of the present disclosure, the surface particle layer 700 can include a lower particle layer 701 at a lower surface of the encapsulation substrate 500 toward the device substrate 100 and an upper particle layer 702 at an upper surface of the encapsulation substrate 500 opposite to the device substrate 100, as shown in FIG. 6. The surface particle layer 700 may not be disposed between the lower surface and the upper surface of the encapsulation substrate 500, in some situations. For example, a side surface of the encapsulation substrate 500 may not be covered by the surface particle layer 700.

The lower particle layer 701 may be made of metal particles which are dispersed at the lower surface of the encapsulation substrate 500. For example, the lower particle layer 701 can be made of the first particles including the same material as the encapsulation substrate 500 and the second particles having a thermal conductivity higher than the first particles. The lower particle layer 701 can have a multi-layer structure. For example, the lower particle layer 701 can have a stacked structure of a first lower layer 711 and a second lower layer 721. The first lower layer 711 can be disposed between the encapsulation substrate 500 and the second lower layer 721. For example, the lower surface of the encapsulation substrate 500 can be in direct contact with the first lower layer 711. The content ratio of the first particles and the second particles in the lower particle layer 701 can be gradually changed as a distance away from the lower surface of the encapsulation substrate 500 increases. For example, the content of the first particles in the second lower layer 721 can be less than the content of the first particles in the first lower layer 711. The content of the second particles in the second lower layer 721 can be greater than the content of the second particles in the first lower layer 711. Thus, in the display apparatus according to another embodiment of the present disclosure, the lower particle layer 701 can be in close contact with the lower surface of the encapsulation substrate 500.

A surface roughness of the lower particle layer 701 can be greater than the surface roughness of the encapsulation substrate 500. The lower particle layer 701 can be in contact with the encapsulating element 400. For example, the encapsulating element 400 can be in direct contact with the second lower layer 721. Thus, in the display apparatus according to another embodiment of the present disclosure, the lower particle layer 701 can be in close contact with the encapsulating element 400. And, in the display apparatus according to another embodiment of the present disclosure, the heat transfer efficiency between the encapsulating element 400 and the lower particle layer 701 can be improved.

The upper particle layer 702 can be made of metal particles, which are dispersed at the upper surface of the encapsulation substrate 500. For example, the upper particle layer 702 can be made of the first particles including the same material as the encapsulation substrate 500 and third particles having a thermal conductivity higher than the first particles. The third particles can include a material different from the second particles. For example, a surface roughness of the upper particle layer 702 can be different from the surface roughness of the lower particle layer 701. The upper particle layer 702 can have a multi-layer structure. For example, the upper particle layer 702 can have a stacked structure of a first upper layer 712 and a second upper layer 722. The first upper layer 712 can be disposed between the encapsulation substrate 500 and the second upper layer 722. For example, the upper surface of the encapsulation substrate 500 can be in direct contact with the first upper layer 712. The content ratio of the first particles and the third particles in the upper particle layer 702 can be gradually changed as a distance from the upper surface of the encapsulation substrate 500 increases. For example, the content of the first particles in the second upper layer 722 can be less than the content of the first particles in the first upper layer 712. The content of the third particles in the second upper layer 722 can be greater than the content of the third particles in the first upper layer 712. Thus, in the display apparatus according to another embodiment of the present disclosure, the upper particle layer 702 can be in close contact with the upper surface of the encapsulation substrate 500.

The third particles can include a material having a thermal conductivity higher than the second particles. For example, the second particles can include aluminum (Al), and the third particles can include copper (Cu). Thus, in the display apparatus according to another embodiment of the present disclosure, the thermal conductivity of the upper particle layer 702 can be higher than the thermal conductivity of the lower particle layer 701. That is, in the display apparatus according to another embodiment of the present disclosure, the heat generated by the operation of the pixel driving circuit and/or the light-emitting device 300 can be rapidly transferred to the encapsulation substrate 500 by the lower particle layer 701, and the heat transferred to the encapsulation substrate 500 can be rapidly dissipated to the outside by the upper particle layer 702. Therefore, in the display apparatus according to another embodiment of the present disclosure, the heat dissipation efficiency can be improved without a decrease in physical strength.

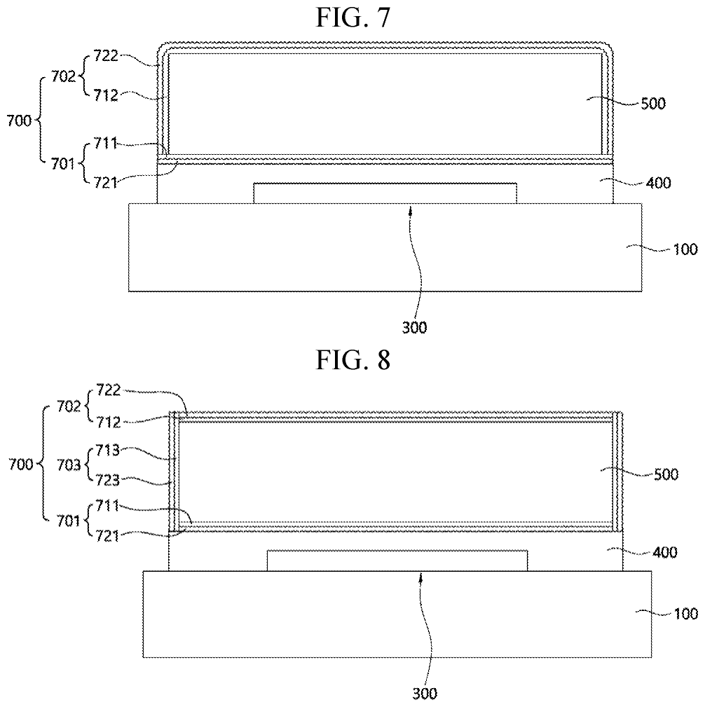

In the display apparatus according to another embodiment of the present disclosure, the upper particle layer 702 can be in contact with the lower particle layer 701. For example, in the display apparatus according to another embodiment of the present disclosure, the side surface of the encapsulation substrate 500 can be covered by the upper particle layer 702, as shown in FIG. 7. Thus, in the display apparatus according to another embodiment of the present disclosure, the heat transfer efficiency between the lower particle layer 701 and the upper particle layer 702 can be improved. Therefore, the display apparatus according to another embodiment of the present disclosure can effectively prevent the gap between the encapsulating element 400 and the surface particle layer 700, and effectively perform the heat dissipation using the surface particle layer 700.

In the display apparatus according to another embodiment of the present disclosure, a portion of the surface particle layer 700 disposed at the side surface of the encapsulation substrate 500 can have a surface roughness different from a portion of the surface particle layer 700 disposed at the upper surface of the encapsulation substrate 500. For example, in the display apparatus according to another embodiment of the present disclosure, the surface particle layer 700 can include the lower particle layer 701 disposed at the lower surface of the encapsulation substrate 500, the upper particle layer 702 disposed at the upper surface of the encapsulation substrate 500, and a side particle layer 703 disposed at the side surface of the encapsulation substrate 500, as shown in FIG. 8. The side particle layer 703 can be in direct contact with the lower particle layer 701 and the upper particle layer 702. For example, in the display apparatus according to another embodiment of the present disclosure, the heat generated by the operation of the pixel driving circuit and the light-emitting device 300 can be dissipated to the outside through the lower particle layer 701, the side particle layer 703 and the upper particle layer 702.

The side particle layer 703 can be made of metal particles, which are dispersed at the side surface of the encapsulation substrate 500. For example, the side particle layer 703 can include the first particles including the same material as the encapsulation substrate 500 and fourth particles having a thermal conductivity higher than the first particles. The side particle layer 703 can have a multi-layer structure. For example, the side particle layer 703 can have a stacked structure of a first side layer 713 and a second side layer 723. The first side layer 713 can be disposed between the encapsulation substrate 500 and the second side layer 723. For example, the side surface of the encapsulation substrate 500 can be in direct contact with the first side layer 713. The content ratio of the first particles and the fourth particles in the side particle layer 703 can be gradually changed as a distance away from the side surface of the encapsulation substrate 500 increases. For example, the content of the first particles in the second side layer 723 can be less than the content of the first particles in the first side layer 713. The content of the fourth particles in the second side layer 723 can be greater than the content of the fourth particles in the first side layer 713. Thus, in the display apparatus according to another embodiment of the present disclosure, the side particle layer 703 can be in close contact with the side surface of the encapsulation substrate 500.

The heat transferred to the lower particle layer 701 can move to the upper particle layer 702 through the side particle layer 703. For example, the fourth particles can have the thermal conductivity higher than the first particles and the second particles of the lower particle layer 701. The fourth particles can have the thermal conductivity lower than the third particles of the upper particle layer 702. The fourth particles can include a material different from the third particles.

A surface roughness of the side particle layer 703 can be less than the surface roughness of the lower particle layer 701 and the surface roughness of the upper particle layer 702. For example, the atomic radius of each of the fourth particles can be less than the atomic radius of each of the third particles. Thus, in the display apparatus according to another embodiment of the present disclosure, the damage of a signal cable electrically connected to the external terminal can be minimized, and the heat dissipation efficiency can be improved.

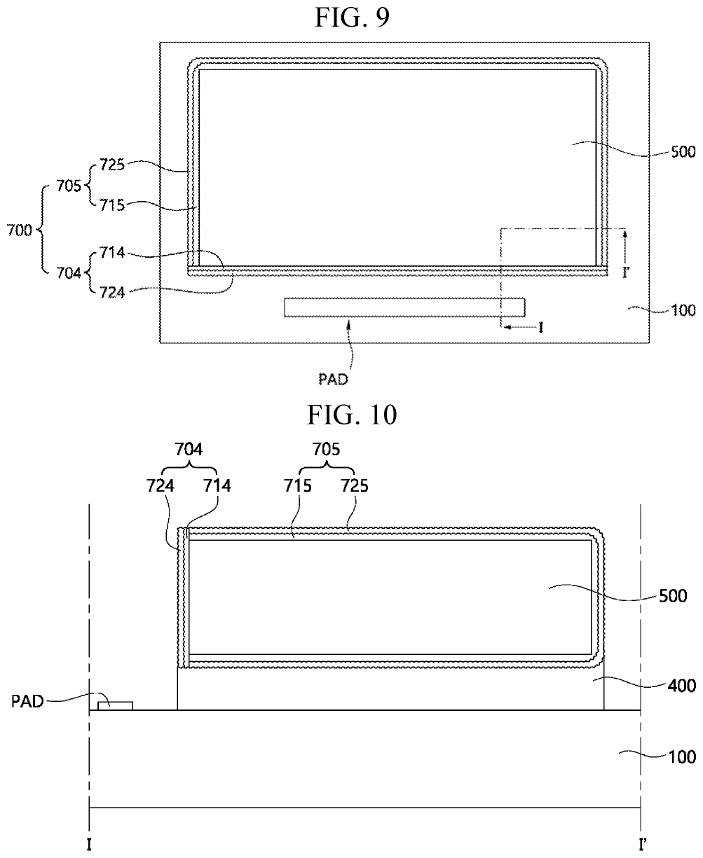

In the display apparatus according to another embodiment of the present disclosure, a pad portion PAD can be disposed on the device substrate 100, as shown in FIGS. 9 and 10. The pad portion PAD can be electrically connected to the external terminal through the signal cable. For example, the gate signal and/or the data signal can be applied through the signal cable and the pad portion PAD. The pad portion PAD can be spaced away from the encapsulating element 400.

A region of the surface particle layer 700 disposed at a front portion of the encapsulation substrate 500 toward the pad portion PAD can have a thermal conductivity higher than the other region of the surface particle layer 700. For example, the surface particle layer 700 can include a front particle layer 704 disposed at the front portion of the encapsulation substrate 500 and a residual particle layer 705 disposed at a portion except the front portion of the encapsulation substrate 500.

The front particle layer 704 can be made of metal particles, which are dispersed at the front portion of the encapsulation substrate 500. For example, the front particle layer 704 can be made of the first particles including the same material as the encapsulation substrate 500 and fifth particles having a thermal conductivity higher than the first particles. The front particle layer 704 can have a multi-layer structure. For example, the front particle layer 704 can have a stacked structure of a first front layer 714 and a second front layer 724. The first front layer 714 can be disposed between the encapsulation substrate 500 and the second front layer 724. For example, the front portion of the encapsulation substrate 500 can be in direct contact with the first front layer 714. For example, the content ratio of the first particles and the fifth particles in the front particle layer 714 can be gradually changed as a distance away from the front portion of the encapsulation substrate 500 increases. For example, the content of the first particles in the second front layer 724 can be less than the content of the first particles in the first front layer 714. The content of the fifth particles in the second front layer 724 can be greater than the content of the fifth particles in the first front layer 714. Thus, in the display apparatus according to another embodiment of the present disclosure, the front particle layer 704 can be in close contact with the front portion of the encapsulation substrate 500.

The residue particle layer 705 can be made of metal particles, which are dispersed at a surface of a portion except the front portion of the encapsulation substrate 500. For example, the residue particle layer 705 can be made of the first particles and sixth particles having a thermal conductivity higher than the first particles. The residue particle layer 705 can have a multi-layer structure. For example, the residue particle layer 705 can have a stacked structure of a first residue layer 715 and a second residue layer 725. The first residue layer 715 can be disposed between the encapsulation substrate 500 and the second residue layer 725. For example, the surface of the portion except the front portion of the encapsulation substrate 500 can be in direct contact with the first residue layer 715. The content ratio of the first particles and the sixth particles in the residue particle layer 705 can be gradually changed as a distance from a surface of the encapsulation substrate 500 increases. For example, the content of the first particles in the second residue layer 725 can be less than the content of the first particles in the first residue layer 715. The content of the sixth particles in the second residue layer 725 can be greater than the content of the sixth particles in the first residue layer 715. Thus, in the display apparatus according to another embodiment of the present disclosure, the residue particle layer 705 can be in close contact with the surface of the encapsulation substrate 500.

A thermal conductivity of the sixth particles can be less than the thermal conductivity of the fifth particles. For example, the fifth particles can include copper (Cu), and the sixth particles can include aluminum (Al). Thus, in the display apparatus according to another embodiment of the present disclosure, the front particle layer 704 can have a thermal conductivity higher than the residue particle layer 705. A surface roughness of the front particle layer 704 can be greater than a surface roughness of the residue particle layer 705. That is, in the display apparatus according to another embodiment of the present disclosure, heat generated by the pad portion PAD can be rapidly dissipated through the front particle layer 704. For example, in the display apparatus according to another embodiment of the present disclosure, the heat generated by the pad portion PAD may not be transferred in a direction of the light-emitting device (e.g., heat from the pad portion PAD can be redirected away from the light-emitting device). Therefore, in the display apparatus according to another embodiment of the present disclosure, the deterioration of the light-emitting layer due to heat can be further minimized.

As a result, the display apparatus according to the embodiments of the present disclosure can include the encapsulating element covering the light-emitting device, the encapsulation substrate on the encapsulating element and the metal particles dispersed at the surface of the encapsulation substrate, in which encapsulation substrate can include a metal, and in which the metal particles can include the first particles including the same material as the encapsulation substrate, and the second particles having the thermal conductivity higher than the first particles.

Thus, in the display apparatus according to the embodiments of the present disclosure, the surface particle layer made of the metal particles can have a surface roughness greater than the encapsulation substrate. That is, in the display apparatus according to the embodiments of the present disclosure, separation of the surface particle layer and the encapsulation substrate can be prevented. Therefore, in the display apparatus according to the embodiments of the present disclosure, damage to the light-emitting device due to external impacts can be sufficiently prevented, and the heat dissipation efficiency can be improved.

What is claimed is:

1. A display apparatus comprising:
at least one light-emitting device on a device substrate;
an encapsulating element on the device substrate, the encapsulating element covering the light-emitting device;
an encapsulation substrate on the encapsulating element, the encapsulation substrate including a metal; and
a surface particle layer surrounding at least a portion of the encapsulation substrate, the surface particle layer including metal particles dispersed at a surface of the encapsulation substrate,
wherein the surface particle layer has a thermal conductivity that is higher than a thermal conductivity of the encapsulation substrate.

2. The display apparatus according to claim 1, wherein a surface roughness of the surface particle layer is greater than a surface roughness of the encapsulation substrate.

3. The display apparatus according to claim 1, wherein the surface particle layer includes first metal particles and second metal particles having a smaller size than the first metal particles.

4. The display apparatus according to claim 1, wherein the first metal particles have an ovoid shape, and
wherein the second metal particles have a spherical shape.

5. The display apparatus according to claim 1, wherein the encapsulating element is in contact with the surface particle layer, and
wherein at least a portion of the surface particle layer is disposed outside of the encapsulating element.

6. The display apparatus according to claim 1, wherein the encapsulation substrate includes a lower surface facing toward the device substrate, an upper surface opposite to the device substrate, and a side surface between the lower surface and the upper surface,
wherein the surface particle layer includes a lower particle layer disposed at the lower surface of the encapsulation substrate, an upper particle layer disposed at the upper surface of the encapsulation substrate, and a side particle layer disposed at the side surface of the encapsulation substrate, and
wherein a surface roughness of the lower particle layer is greater than a surface roughness of the upper particle layer.

7. The display apparatus according to claim 6, wherein a surface roughness of the side particle layer is different than the surface roughness of the upper particle layer.

8. The display apparatus according to claim 6, wherein a thermal conductivity of the upper particle layer is higher than a thermal conductivity of the lower particle layer.

9. The display apparatus according to claim 8, wherein a thermal conductivity of the side particle layer is different than the thermal conductivity of the upper particle layer.

10. The display apparatus according to claim 1, further comprising a pad portion disposed on the device substrate, the pad portion being spaced away from the encapsulating element,
wherein the side surface of the encapsulation substrate includes a front portion facing toward the pad portion,
wherein the surface particle layer includes a first region disposed on the front portion of the encapsulation substrate and a second region disposed outside of the front potion, and
wherein a thermal conductivity of the first region is higher than a thermal conductivity of the second region.

11. The display apparatus according to claim 10, wherein a surface roughness of the first region is different than a surface roughness of the second region.

12. The display apparatus according to claim 1, wherein the surface particle layer fully surrounds the encapsulation substrate.

13. A display apparatus comprising:
at least one light-emitting device on a device substrate;
an encapsulation substrate on the light-emitting device, the encapsulation substrate including a metal;
a lower particle layer including first particles and second particles dispersed on a lower surface of the encapsulation substrate facing toward the device substrate;
an encapsulating element between the light-emitting device and the lower particle layer; and
an upper particle layer including the first particles and third particles are dispersed on an upper surface of the encapsulation substrate opposite to the device substrate,
wherein the first particles include a same metal as the encapsulation substrate, and
wherein the second particles and the third particles include a metal having higher thermal conductivity than the first particles.

14. The display apparatus according to claim 13, wherein a thermal conductivity of the third particles is higher than a thermal conductivity of the second particles.

15. The display apparatus according to claim 13, wherein each of the lower particle layer and the upper particle layer includes a first particle layer in contact with the encapsulation substrate and a second particle layer on the first particle layer, and
wherein a content of the first particles in the second particle layer is less than a content of the first particles in the first particle layer.

16. The display apparatus according to claim 15, wherein each of the lower particle layer and the upper particle layer further includes a third particle layer between the first particle layer and the second particle layer, and
wherein a content of the first particles in the third particle layer is between the content of the first particles in the first particle layer and the content of the first particles in the second particle layer.

17. The display apparatus according to claim 13, further comprising a side particle layer including the first particles and fourth particles dispersed on a side surface of the encapsulation substrate disposed between the lower surface of the encapsulation substrate and the upper surface of the encapsulation substrate,
wherein a thermal conductivity of the fourth particles is higher than a thermal conductivity of the first particles and a thermal conductivity of the second particles.

18. The display apparatus according to claim 17, wherein the fourth particles include a same material as the third particles.

19. The display apparatus according to claim 17, wherein the side particle layer is in contact with the lower particle layer and the upper particle layer.

20. The display apparatus according to claim 13, wherein a surface roughness of the lower particle layer or a surface roughness of the upper particle layer is greater than a surface roughness of the encapsulation substrate.
